(19) United States
(12) Patent Application Publication
(10) Pub. No.: US 2008/0318421 A1
(43) Pub. Date: Dec. 25, 2008

(54) METHODS OF FORMING FILMS OF A SEMICONDUCTOR DEVICE

(75) Inventors: Jong-Ho Yun, Gyeonggi-do (KR); Gil-Heyun Choi, Seoul (KR); Jong-Myeong Lee, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/137,059

(22) Filed: Jun. 11, 2008

(30) Foreign Application Priority Data
Jun. 22, 2007 (KR) 10-2007-0061684

(51) Int. Cl. H01L 21/3205; H01L 21/3065

(52) U.S. Cl. 438/669; 438/694; 257/E21.295; 257/E21.218

(57) ABSTRACT

There is provided a method of forming a film of a semiconductor device. The method includes a step of adsorbing a liquefied metal ion source on the substrate; rinsing the substrate to remove any liquefied metal ion source that is not adsorbed to the substrate; depositing a metal layer on the substrate by reducing the liquefied metal ion source that is adsorbed on the substrate with a liquefied reducing agent; and rinsing the substrate to remove the remaining liquefied reducing agent and any reaction residual.

### CROSS-REFERENCE TO RELATED APPLICATIONS

This U.S. non-provisional patent application claims priority under 35 U.S.C. §119 of Korean Patent Application No. 10-2007-0061684, filed on Jun. 22, 2007, the disclosure of which is hereby incorporated by reference in its entirety.

### FIELD AND BACKGROUND OF THE INVENTION

The present invention disclosed herein relates to methods of forming films of semiconductor devices semiconductor device, and more particularly, to a method of forming a film of a semiconductor device using an electroless plating process.

Generally, a film of a semiconductor device may be formed using one of a chemical vapor deposition (CVD) process, a physical vapor deposition (PVD) process, an electrochemical deposition (ECD) process and an electroless plating process. The electrochemical deposition (ECD) process may get a metal layer containing an impurity of comparatively small quantity and having a relatively better characteristic than the other processes. However, since the electrochemical deposition (ECD) process is a method of depositing a metal layer using an external power supply, it has disadvantages that applying it to a large wafer is difficult due to a voltage drop and the process is complicated because of requiring a good seed layer.

To solve the above disadvantages, a method of depositing a metal layer using an ionization difference between a reducing agent and an oxidizing agent in a solution after activating a surface of a wafer has been proposed in U.S. Pat. No. 6,126,989. Since the method does not require a process of forming a copper seed layer and a deposition is uniformly performed over the whole of the wafer not using an external power supply, it has an advantage of improving a degradation of uniformity due to a voltage down. Also, because the method does not require a process of forming a copper seed layer, the process may be simplified to improve productivity. For example, the electroless plating process disclosed in U.S. Pat. No. 6,126,989 may become simplified as compared with electrochemical deposition (ECD).

### SUMMARY OF THE INVENTION

A method of forming a film of a semiconductor device is provided. The method comprises adsorbing a liquefied metal ion source on a substrate, removing any of the liquefied metal ion source that is not adsorbed on the substrate with a rinsing solution, reducing the adsorbed liquefied metal ion source to a metal layer with a liquefied reducing agent; and removing any remaining liquefied reducing agent and any reaction residual on the substrate with a rinsing solution to form a film of a semiconductor device.

Example embodiments provide a method of forming a film of a semiconductor device which may include a step of providing a substrate; a first metal ion adsorbing step of providing a first liquefied metal ion source to the substrate to adsorb the first liquefied metal ion source on the substrate; a first rinse step of providing a rinsing solution to the substrate to remove the first liquefied metal ion source that is not adsorbed to the substrate; a first metal ion reduction step of depositing a first metal layer on the substrate by reducing the first liquefied metal ion source that is adsorbed on the substrate with a first liquefied reducing agent; a second rinse step of providing the rinsing solution to the substrate to remove the remaining first liquefied reducing agent and a first reaction residual; a second metal ion adsorbing step of providing a second liquefied metal ion source to the substrate to adsorb the second liquefied metal ion source on the first metal layer; a third rinse step of providing the rinsing solution to the substrate to remove the second liquefied metal ion source that is not adsorbed to the first metal layer; a second metal ion reduction step of depositing a laminate metal layer that a second metal layer is stacked on the first metal layer by reducing the second liquefied metal ion source that is adsorbed on the first metal layer with a second liquefied reducing agent; and a fourth rinse step of providing the rinsing solution to the substrate to remove the remaining second liquefied reducing agent and a second reaction residual.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a schematic view illustrating a method of forming a film of a semiconductor device in accordance with example embodiments of the present invention;

FIG. 2 is a flow chart representing a method of forming a film of a semiconductor device in accordance with example embodiments of the present invention;

FIG. 3 is a graph representing a method of forming a film of a semiconductor device in accordance with example embodiments of the present invention;

FIGS. 4a and 4b are schematic views illustrating a method of forming a film of a semiconductor device in accordance with other example embodiments of the present invention; and

FIG. 5 is a flow chart representing a method of forming a film of a semiconductor device in accordance with other example embodiments of the present invention.

### DETAILED DESCRIPTION OF PREFERRED EMBODIMENTS

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Embodiments of the present invention may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

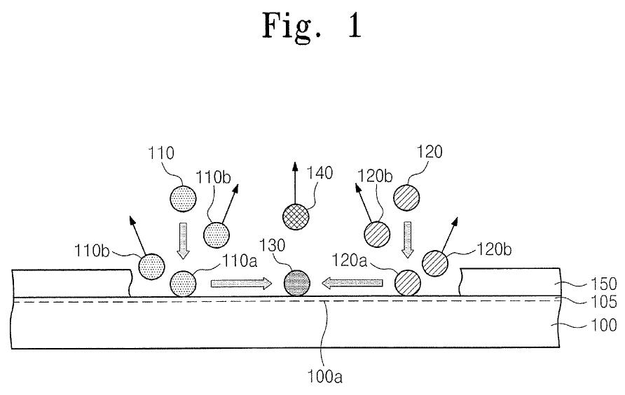

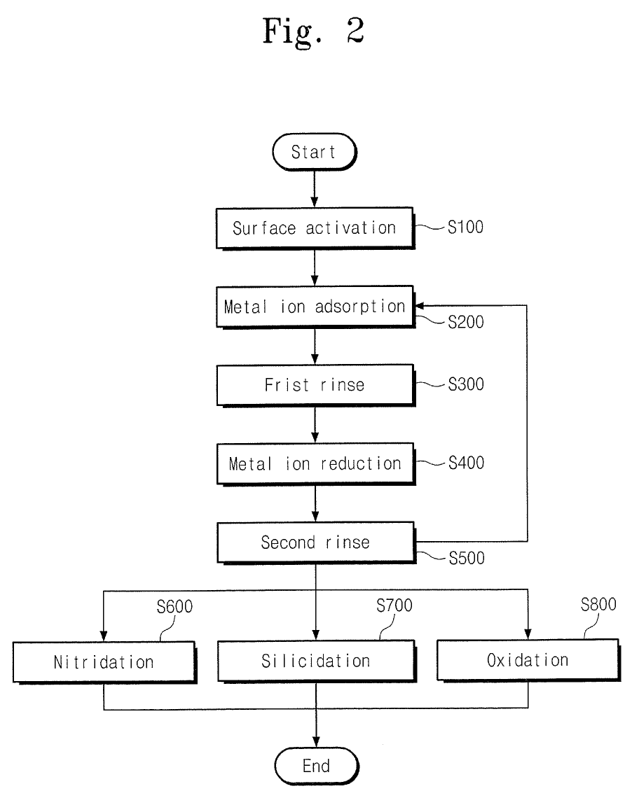

FIG. 1 is a schematic view illustrating a method of forming a film of a semiconductor device in accordance with example embodiments of the present invention and FIG. 2 is a flow chart representing a method of forming a film of a semiconductor device in accordance with example embodiments of the present invention.

Referring to FIGS. 1 and 2, a metal ion source 110 may be provided to a substrate 100 to deposit or plate a surface 100a of the substrate 100 with a metal layer 150 using an electroless plating process. A metal ion adsorbing step (S200) may be conducted and the metal ion source 110 may be adsorbed on the surface 100a of the substrate 100. The substrate 100 in the example embodiments may be a semiconductor wafer such as a silicon wafer, a conductive layer or an insulating layer. The selection of the substrate 100 will be within the skill of one in the art.

The metal ion source 110 may be provided to the substrate 100 using a single type method, that is, a method of spraying the metal ion source 110 in a liquefied state on the substrate 100 mounted on the chuck through a dispense arm. Alternatively, the metal ion source 110 may be provided to the substrate 100 using a batch type method, that is, dipping the substrate 100 in a bath filled with the metal ion source 110 in a liquid state. The adsorbed metal ion source 110a exists on the surface 100a of the substrate 100. Some of the metal ion source may not be adsorbed into the surface 110 of the substrate 100, and is shown as a non-adsorbed metal ion source 110b.

The metal ion source 110 may be any material including metal that may be deposited on the surface 100a of the substrate 100, for instance, a metallic salt. For example, the metal ion source 110 may include CuSO₄ in the case of depositing a copper (Cu) film, CoSO₄ in the case of depositing a cobalt (Co) film, and NiSO₄ in the case of depositing a nickel (Ni) film. Differently, the metal ion source 110 may be a metallic salt including salts of gold (Au), silver (Ag), palladium (Pd), platinum (Pt), ruthenium (Ru), rhenium (Re), tin (Sn), ferrum (Fe), plumbum (Pb), or cadmium (Cd).

It is recognized by those skilled in the art that the term “deposition” as used in the embodiments has the same meaning as the term “plating”.

Selectively, a surface activation process (S100) to the surface 100a of the substrate 100 may be performed before the metal ion adsorbing step (S200). The surface activation process (S100) may comprise forming material on the surface 100a of the substrate 100. The material may become a growth nucleus of the metal layer 150 and may serve as a catalyst for a plating reaction in an electroless plating process. The surface activation process (S100) may improve adhesion between the metal layer 150 and the substrate 100, and may form the metal layer 150 densely and uniformly. For example, in the surface activation process (S100), palladium salt may be formed on the substrate 100 to form a palladium layer 105 as a surface activation process layer on the surface 100a of the substrate 100. Alternatively, the palladium layer 105 may be formed on the surface 100a of the substrate 100 after removing oxides on the substrate 100 using a plasma etching process. The metal layer 150 may be formed only on the surface 100a where the palladium layer is formed.

After the metal ion adsorbing step (S200) is performed, a first rinse step (S300) may be performed. The first rinse step (S300) may comprise rinsing the surface 100a of the substrate 100 to remove a non-adsorbed metal ion source 110b from the substrate 100. The first rinse step (S300) may be performed using a method (single type) of spraying a rinsing solution on the substrate 100 mounted on a chuck of a dispense arm. Alternatively, the first rinse step (S300) may be performed using a method (batch type) of dipping the substrate 100 in a bath filled with a rinsing solution. In the case of performing the first rinse step (S300) using the single type method, the spraying of the rinse solution is controlled to remove a non-adsorbed metal ion source 110b and leave an adsorbing metal ion source 110a. Here, the rinsing solution may be selected from one of deionized water (DIW) and various cleaning solutions, such as Standard Clean Solution #1 (SC-1) comprising ammonium hydroxide/hydrogen peroxide/deionized water, Standard Cleaning Solution #2 (SC-2) comprising hydrochloric acid/hydrogen peroxide/deionized water, HF, HF/NH₃/deionized water, HF/H₂SO₄, trichloroethylene and isopropyl alcohol, or combinations thereof.

After the first rinse step (S300) is performed, a metal ion reduction step (S400) may be performed. The metal ion reduction step (S400) may comprise using a reducing agent 120 to reduce a metal ion from the adsorbing metal ion source 110a. As a result, a metal layer 130 is deposited or formed on the surface 100a of the substrate 100. In the metal ion reduction step (S400), an electroless plating process may be performed. The electroless plating process may comprise depositing the metal layer 130 on the surface 100a of the substrate 100 by a reduction reaction of the adsorbing metal ion source 110a wherein the adsorbing metal ion source 110a accepts an electron generated from an oxidation reaction of the reducing agent 120 without an external power supply to reduce the metal.

For example, in the case of reducing copper (Cu), the reducing agent 120 may be potassium borohydride (KBH₄), dimethylamineborane, hypophosphite, or hydrazine or the like. For another example, in the case of reducing cobalt or nickel, the reducing agent 120 may be boride such as dimethylamineborane (DMAB), diethylamineborane, morpholineborane, pyridineamineborane, piperidineborane, ethylenediamineborane, ethylenediaminebisborane, t-buthylamineborane, imidazoleborane, methoxyethylamineborane, or sodium borohydride.

The metal ion reduction step (S400) may be performed using the single type, that is, spraying the liquefied reducing agent 120 on the substrate 100 mounted on a chuck of a dispense arm. Alternatively, the metal ion reduction step (S400) may be performed using the batch type, that is, by dipping the substrate 100 into a bath filled with the liquefied reducing agent 120. In the metal ion reduction step (S400), the reducing agent may comprise a reacting reducing agent 120a participating in a reduction reaction.

In the present invention, the metal ion source 110 may be provided to the substrate 100 during the metal ion adsorbing step (S200) and the reducing agent 120 may be provided separately to the substrate 100 during the metal ion reduction step (S400). In other words, since the metal ion source 110 and the reducing agent 120 are separately provided to the substrate 100, it is not required to make a mixture of the metal ion source 110 and the reducing agent 120. Thus, a chemical degradation may not occur due to the mixing of the metal ion source 110 and the reducing agent 120. Also, it is not required to use a complexing agent for controlling pH of the mixture of the metal ion source 110 and the reducing agent 120, nor is a stabilizer for preventing a homogeneous reaction of the metal ion source 110 and the reducing agent 120 required.

After the metal ion reduction step (S400) is performed, a second rinse step (S500) may be performed. The second rinse step (S500) may comprise rinsing the substrate 100 with a solution to remove the remaining reducing agent 120b from the substrate 100. In the second rinse step (S500), a reaction residual 140 may be removed from the substrate 100 together with the remaining reducing agent 120b. The second rinse step (S500) may be performed using a method (single type) of spraying a rinsing solution on the substrate 100 mounted on a chuck of a dispense arm. Alternatively, the second rinse step (S500) may be performed using a method (batch type) of dipping the substrate 100 in a bath filled with a rinsing solution. Here, the rinsing solution may be selected from one of deionized water (DIW) and various cleaning solutions, such as Standard Clean Solution #1 (SC-1) comprising ammonium hydroxide/hydrogen peroxide/deionized water, Standard Cleaning Solution #2 (SC-2) comprising hydrochloric acid/hydrogen peroxide/deionized water, HF, HF/NH₃/deionized water, HF/H₂SO₄, trichloroethylene and isopropyl alcohol, or combinations thereof.

As described above, in a manner similar to an atomic layer deposition (ALD) process, the metal ion adsorbing step (S200), the metal ion reduction step (S400) and the second rinse step (S500) may be sequentially performed to deposit the metal layer 150 on the substrate 100. The metal layer 150 may be deposited at a rate of several hundreds angstroms/min or more. For convenience, the metal layer 150 is drawn discontinuously in FIG. 1. The metal layer 150 may be deposited over the whole of the surface 100a of the substrate 100 or selectively deposited on the surface 100a of the substrate 100. If necessary, the metal ion adsorbing step (S200), the metal ion reduction step (S400) and the second rinse step (S500) may be repeatedly performed to precisely control a thickness of the metal layer 150.

A metal layer 150 may include a single atom. Alternatively, the metal layer 150 may include an alloy, or a combination of metal and impurity (e.g., nonmetal). That is, if the metal ion source 120 is properly selected in the metal ion adsorbing step (S200), the metal layer 150 formed may include alloys of various alloys such as cobalt, nickel, and copper. For example, the cobalt alloy may include CoP, CoB, CoWP, CoWB, CoZnP, CoFeP, CoReP, CoCuP, CoMoP, CoMoB and CoMnP. For example, the nickel alloy may include NiP, NiB, NiWP, NiCoP, NiCuP, NiFeP, NiReP, NiCoReP and NiCoWP. For example, the copper alloy may include CuZn, CuAg and CuCa.

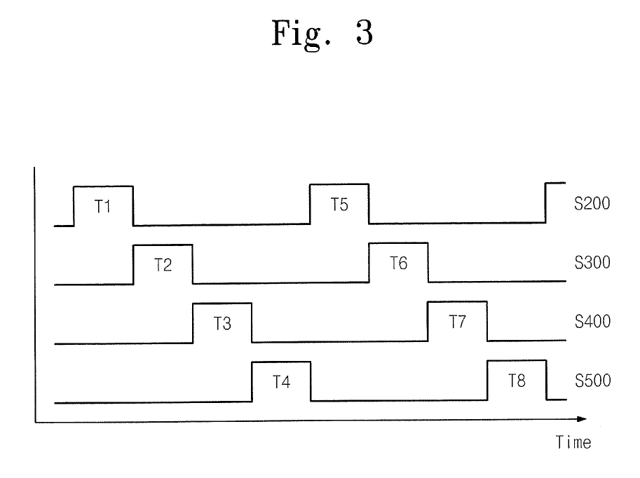

FIG. 3 is a graph representing a process time of an each step in a method of forming a film of a semiconductor device in accordance with example embodiments of the present invention.

Referring to FIG. 3, the first rinse step (S300) may be performed for a second duration (T2) after the metal ion adsorbing step (S200) may be performed for a first duration (T1). After this, the metal ion reduction step (S400) may be performed for a third duration (T3) and then, the second rinse step (S500) may be performed for a fourth duration (T4). If necessary, the metal ion adsorbing step (S200) and the first rinse step (S300) may be repeatedly performed for a fifth duration (T5) and a sixth duration (T6), respectively and then, the metal ion reduction step (S400) and the second rinse step (S500) may be repeatedly performed for a seventh duration (T7) and a eighth duration (T8), respectively. In one embodiment, the first duration (T1) through the eighth duration (T8) should be set to a time that reaction sufficiently may occur in each step of the metal ion adsorbing step (S200) through the second rinse step (S500). The first duration (T1) through the eighth duration (T8) may be about 0.01 to 100 seconds, respectively.

The series of the steps (S200 through S500) may be performed at room temperature (e.g., 25° C.). The process temperature of each step of the metal ion adsorbing step S200 through the second rinse step (S500) may be increased to activate the reaction of the each step of the metal ion adsorbing step (S200) through the second rinse step (S500) all the more. A process temperature of each step of the metal ion adsorbing step (S200) through the second rinse step (S500) of 100° C. or less may be sufficient to activate each reaction.

Referring back to FIGS. 1 and 2, if necessary, a nitride layer, a silicide layer or an oxide layer may be deposited on the substrate 100. After the metal layer 150 is formed on the substrate 100 using a series of the steps (S200 through S500), a further process step such as a nitration treatment for nitrifying the metal layer 150 (S600), a silicide treatment (S700) of the metal layer 150 or an oxidation treatment (S800) for oxidizing the metal layer 150 may selectively be performed. These further process steps (S600 through S800) may be performed, for example, using a rapid thermal process (RTP) method, an ultra high vacuum (UHV) chamber or an annealing process by convection or conduction. A temperature of the further process steps (S600 through S800) may be conducted at 100° C. to 1,500° C. at a pressure of about 10⁻⁸ Torr to 5 atmospheric pressure.

If the method of the present invention is used, a barrier of a contact hole or a via hole having a high aspect ratio, or top and bottom electrodes of a capacitor having a great height as well as a flat metal layer may be conformally deposited to provide a film having a superior step coverage.

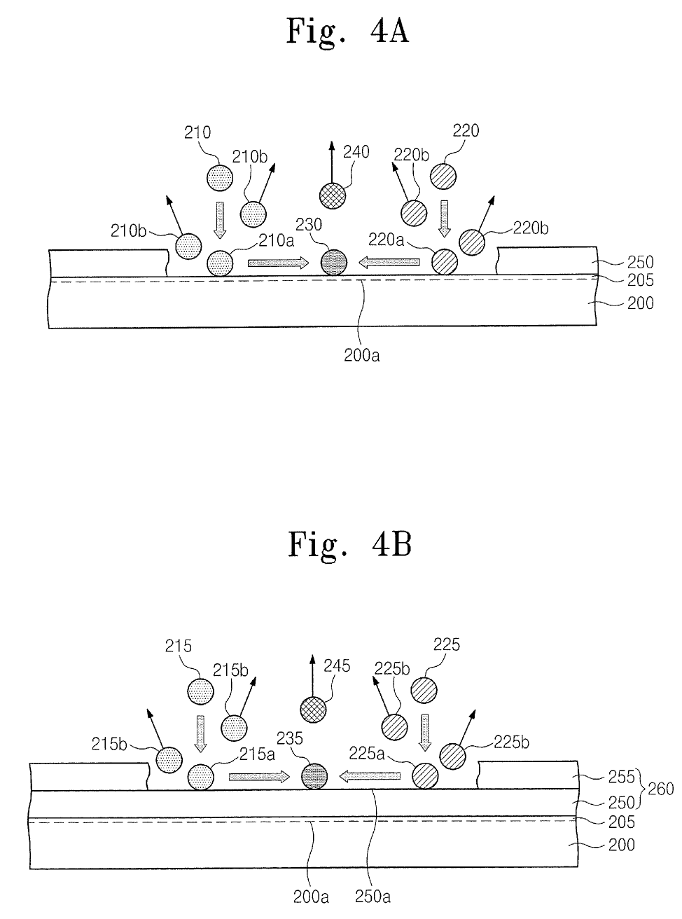

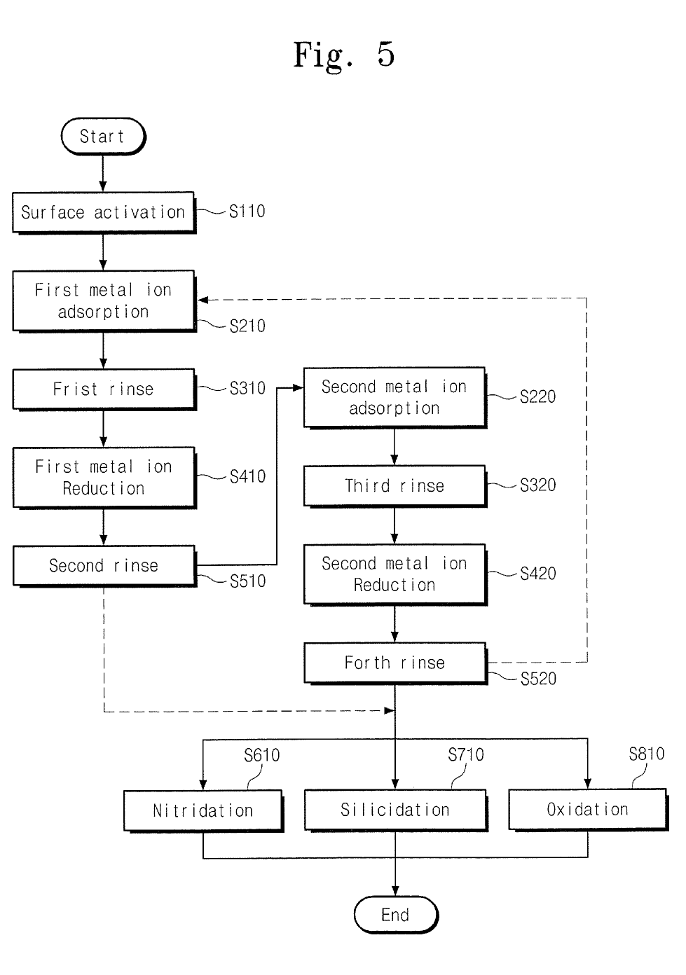

FIGS. 4a and 4b are schematic views illustrating a method of forming a film of a semiconductor device in accordance with example embodiments of the present invention and FIG. 5 is a flow chart representing a method of forming a film of a semiconductor device in accordance with other example embodiments of the present invention.

Since the second embodiment is similar to the above described first embodiment, differences between the two embodiments will be primarily described in detail.

Referring to FIGS. 4a and 5, a first metal ion source 210 may be deposited on the surface 200a of the substrate 200 and a first metal layer 250 is provided using an electroless plating process. The first metal ion source 210 is liquefied and may be provided to the substrate 200 using the single or batch types described in the first embodiment. A first adsorbing metal ion source 210a may exist on the surface 200a of the substrate 200 by the first metal ion adsorbing step (S210) and a non-adsorbing metal ion source 210b may exist on the substrate 200. The first metal ion source 210 may be a metallic salt including metal to be deposited on the surface 200a of the substrate 200 such as copper, nickel or cobalt. For example, the first ion metal source 210 may be CoSO₄.

Selectively, a surface activation process (S110) to the surface 200a of the substrate 200 may be performed before the metal ion adsorbing step (S210). The surface activation process (S110) may comprises forming material on the surface 200a of the substrate 200. The material may become a growth nucleus of the metal layer 250 and may serve as a catalyst of a plating reaction in an electroless plating process. For example, in the surface activation process (S110), palladium salt may be provided to the substrate 200 to form a palladium layer 205 on the surface 200a of the substrate 200. The palladium layer 205 may improve adhesion between the first metal layer 250 and the substrate 200 or may deposit the first metal layer 250 densely and uniformly.

After the metal ion adsorbing step (S210), a first rinse step (S310) may be performed. The first rinse step (S310) may comprise rinsing the surface 200a of the substrate 200 with a rinsing solution to remove the first non-adsorbing metal ion source 210b from the substrate 200. Here, the rinsing solution may be selected from one of deionized water (DIW) and various cleaning solutions discussed previously, or combinations thereof. The first rinse step (S310) may be performed using the single type or the batch type described in the first embodiment.

After the first rinse step (S310) is performed, a first metal ion reduction step (S410) may be performed. The first metal ion reduction step (S400) may comprise reducing the first metal ion source 210a on the substrate with a first reducing agent 220. For example, in the first metal ion reduction step (S410), the first metal 230 deposited on the surface 200a may be reduced by an oxidation reaction of the first reducing agent 220 and a reduction reaction of the first adsorbing metal ion source 210a. The first metal ion reduction step (S410) may be performed using the single type or the batch type described in the first embodiment. In the first metal ion reduction step (S410), the first reducing agent may be divided into a first reacting reducing solution 220a participating in a reduction reaction and a first remaining reducing agent 220b remaining on the substrate 200. If the first metal ion source 210 is a metallic salt, for example, a salt of cobalt (Co), the first reducing agent may be, for example, dimethylamineborane (DMAB).

After the metal ion reduction step (S410) is performed, a second rinse step (S510) may be performed. The second rinse step (S510) may comprise rinsing the substrate 200 with a rinsing solution to remove the first remaining reducing agent 220b from the substrate 200. Here, the rinsing solution may be selected from one of deionized water (DIW) and various solvents, or combinations thereof. In the second rinse step (S500), a first reaction residual 240 may be removed from the substrate 200 together with the first remaining reducing agent 220b. The second rinse step (S510) may be performed using the single type or the batch type.

The first metal layer 250 may be deposited on the surface 200a of the substrate 200 by the series of the steps described above. The metal layer 250 may be deposited over the whole of the surface 200a of the substrate 200 or selectively deposited on the surface 200a of the substrate 200. If necessary, the first metal ion adsorbing step (S210), the first rinse step (S310), the first metal ion reduction step (S410) and the second rinse step (S510) may be repeatedly performed to precisely control a thickness of the metal layer 250.

Referring to FIGS. 4b and 5, after the second rinse step (S510) is performed, a second metal ion source 215 may be adsorbed on a surface 250a of the substrate 200. A second metal ion source 215a may exist on the surface 250a of the first metal layer 250 and a non-adsorbing metal ion source 215b may exist on the second metal layer 250 by the second metal ion adsorbing step (S220). The second metal ion source 215 may be a metallic salt including metal to be deposited on the surface 250a of the first metal layer 250 such as copper, nickel or cobalt. For instance, the material may be metal different from the metal included in the first metal ion source (210 of FIG. 4). For example, if the first metal ion source 210 is CoSO₄, the second metal ion source 215 may be NiSO₄.

After the second metal ion adsorbing step (S220) is performed, a third rinse step (S320) may be performed. The third rinse step (S320) may comprise rinsing the surface 250a of the first metal layer 250 with a rinsing solution to remove the non-adsorbed metal ion source 215b from the first metal layer 250. Here, the rinsing solution may be selected from one of deionized water (DIW) and various cleaning solutions discussed previously, or combinations thereof. The third rinse step (S320) may be performed using the single type or the batch type described in the first embodiment.

After the third rinse step (S320) is performed, a second metal ion reduction step (S420) may be performed. The second metal ion reduction step (S420) may comprise providing a second reducing agent 225 onto the first metal layer 250 to reduce a second metal ion from the second adsorbing metal ion source 215a. In the second metal ion reduction step (S420), the second metal 235 may be reduced by an oxidation reaction of the second reducing agent 225 and a reduction reaction of the second adsorbing metal ion source 215a. The second metal ion reduction step (S420) may be performed using the single type or the batch type. In the second metal ion reduction step (S420), the second reducing agent 225 may be divided into a second reacting reducing agent 225a participating in the metal ion reduction reaction and a second remaining reducing agent 225b remaining on the first metal layer 250. For example, if the second metal ion source 215 may include a metallic salt containing nickel (Ni), the second reducing agent 225 may be dimethylamineborane (DMAB).

After the second metal ion reduction step (S420) is performed, a fourth rinse step (S520) may be performed. The fourth rinse step (S520) may comprise rinsing the first metal layer 250 with a rinsing solution to remove the second remaining reducing agent 225b from the first metal layer 250. Here, the rinsing solution may be selected from one of deionized water (DIW) and various solvents, or combinations thereof. In the fourth rinse step (S520), a second reaction residual 245 may be removed from the first metal layer 250 together with the second remaining reducing agent 225b. The fourth rinse step (S520) may be performed using the single type or the batch type.

The second metal layer 255, for example, a nickel layer, is deposited on the surface 250a of the first metal layer 250 by the series of the steps described above. Thus, a metal layer 260 is deposited on the surface 200a of the substrate 200. Here, the metal layer 260 may comprise the first metal layer 250 such as a cobalt layer and the second metal layer 255 such as a nickel layer stacked on the first metal layer 250 to provide a laminated structure. If necessary, the second metal ion adsorbing step (S220), the third rinse step (S320), the second metal ion reduction step (S420) and the fourth rinse step (S520) may be repeatedly performed to precisely control the thickness of the second metal layer 255.

After the second metal layer 255 is formed on the first metal layer 250, the first metal ion adsorbing step (S210) through the second rinse step (S510) are further performed to form the metal layer 260 deposited on the second metal layer 255. Selectively, the second metal ion adsorbing step (S220) through the fourth rinse step (S520) may be further performed so that the first metal layer 250 and the second metal layer 255 may be deposited several times.

At least one of the first and second metal layers 250 and 255 may be an alloy by selection of the first metal ion source 210 and the second metal ion source 215. Also, the first metal layer 250 is formed of metal and the second metal layer 255 is formed of nonmetal and vice versa by selection of the first metal ion source 210 and the second metal ion source 215. For example, the first metal layer 250 may be formed of cobalt alloy and the second metal layer 255 may be formed of nickel alloy.

After the metal layer 260 is formed on the surface 200a of the substrate 200 using a series of the steps (S210 through S520) described above, a succeeding process such as a nitration treatment (S610) for nitrifying the metal layer 150, a silicide treatment (S710) of the metal layer 150 or an oxidation treatment (S810) for oxidizing the metal layer 150 may selectively be performed.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of forming a film of a semiconductor device, the method comprising:
adsorbing a liquefied metal ion source on a substrate;
removing any of the liquefied metal ion source that is not adsorbed on the substrate with a rinsing solution;
reducing the adsorbed liquefied metal ion source to a metal layer with a liquefied reducing agent; and
removing any remaining liquefied reducing agent and any reaction residual on the substrate with the rinsing solution to form a film of a semiconductor device.

2. The method of claim 1, further comprising activating the substrate prior to adsorbing the liquefied metal ion source on the substrate.

3. The method of claim 2, wherein activating the substrate comprises forming a palladium layer on the substrate, with or without performing a plasma etching process on the substrate.

4. The method of claim 1, wherein the liquefied metal ion source comprises a metallic salt including any one of copper (Cu), cobalt (Co), nickel (Ni), gold (Au), silver (Ag), palladium (Pd), platinum (Pt), ruthenium (Ru), rhenium (Re), tin (Sn), ferrum (Fe), plumbum (Pb), cadmium (Cd), or alloys or combinations thereof.

5. The method of claim 1, wherein the liquefied reducing agent comprises any one of the group consisting of potassium borohydride (KBH₄), hypophosphite, hydrazine, dimethylamineborane, diethylamineborane, morpholineborane, pyridineamineborane, piperidineborane, ethylenediamineborane, ethylenediaminebisborane, t-buthylamineborane, imidazoleborane, methoxyethylamineborane, and sodium borohydride.

6. The method of claim 1, wherein the rinsing solution comprises deionized water.

7. The method of claim 1, wherein each step is performed for 0.01 through 100 sec.

8. The method of claim 1, wherein each step is performed at 100° C. or less.

9. The method of claim 8, wherein each step is performed at 25° C. to 100° C.

10. The method of claim 1, wherein each step is performed by mounting the substrate on a chuck or dipping the substrate in a bath.

11. The method of claim 1, wherein the metal layer comprises a single atom, an alloy, or a combination of metal and nonmetal.

12. The method of claim 1, further comprising a step of a nitration treatment for nitrifying the metal layer, of a silicide treatment of the metal layer or of an oxidation treatment for oxidizing the metal layer.

13. The method of claim 1, wherein the substrate includes a semiconductor wafer, a conductive layer or an insulating layer.

14. A method of forming a film of a semiconductor device, the method comprising:
adsorbing liquefied metal ion sources on the substrate, the liquefied metal ion sources comprising at least two different kinds of liquefied metallic salt;
reducing the liquefied metal ion sources on the substrate to a laminated metal layer, wherein one of the liquefied reducing agents reduces one of the liquefied metal ion sources respectively; and
rinsing the substrate to provide a film on a semiconductor device.

15. The method of claim 14, wherein the liquefied metallic salt comprises any one of the group consisting of copper (Cu), cobalt (Co), nickel (Ni), gold (Au), silver (Ag), palladium (Pd), platinum (Pt), ruthenium (Ru), rhenium (Re), tin (Sn), ferrum (Fe), plumbum (Pb), cadmium (Cd), and alloys and combinations thereof.

16. The method of claim 15, wherein the liquefied reducing agent comprises any one of the group consisting of potassium borohydride (KBH₄), hypophosphite, hydrazine, dimethylamineborane, diethylamineborane, morpholineborane, pyridineamineborane, piperidineborane, ethylenediamineborane, ethylenediaminebisborane, t-buthylamineborane, imidazoleborane, methoxyethylamineborane, and sodium borohydride.

17. The method of claim 14, further comprising activating the substrate prior to adsorbing the liquefied metal ion sources on the substrate.

18. The method of claim 17, wherein activating the substrate comprises forming a palladium layer on the substrate, with or without performing a plasma etching process on the substrate.

19. The method of claim 14, further comprising a nitridation treatment of the metal layer, of a silicidation treatment of the metal layer, or of an oxidation treatment of the metal layer after rinsing the substrate.

20. The method of claim 14, wherein the step of rinsing the substrate comprises:
removing liquefied metal ion sources that are not adsorbed on the substrate; and
removing remaining liquefied reducing agents and by-products.
